(19) United States
(12) Patent Application Publication
(10) Pub. No.: US 2024/0234464 A9
(43) Pub. Date: Jul. 11, 2024

(54) IMAGING DEVICE AND ELECTRONIC APPARATUS

(71) Applicant: Sony Semiconductor Solutions Corporation, Kanagawa (JP)

(72) Inventor: Keiji Sasano, Tokyo (JP)

(21) Appl. No.: 18/548,412

(22) PCT Filed: Mar. 31, 2021
(86) PCT No.: PCT/JP2021/013810

§ 371 Date: Aug. 30, 2023

(51) Int. Cl. H01L 27/146

(52) U.S. Cl. CPC H01L 27/14627; H01L 27/14623; H01L 27/1465

(57) ABSTRACT

An imaging device of an embodiment of the present disclosure includes: a pixel array part in which a plurality of pixels is disposed in a row direction and a column direction; a photoelectric conversion layer including a compound semiconductor; and an optical member in which a first refractive index portion and a second refractive index portion having mutually different refractive indices are disposed alternately from a central part to an outer peripheral part. The optical member is disposed on side of a light entering surface of the photoelectric conversion layer to straddle the plurality of pixels adjacent at least in the row direction or the column direction.

### TECHNICAL FIELD

The present disclosure relates to an imaging device to be used as, for example, an infrared sensor and an electronic apparatus with the imaging device.

### BACKGROUND ART

For example, PTL 1 discloses an integrated imaging device for infrared rays, the imaging device having a cavity, within which a sensor is placed, between a substrate and a silicon-made cover. On a surface of the cover, which is opposite to side where the cavity is provided, a surface structure for directing entering radiations is provided.

### CITATION LIST

### Patent Literature

PTL 1: Japanese Unexamined Patent Application Publication (Published Japanese Translation of PCT Application) No. JP2016-526155

### SUMMARY OF THE INVENTION

In the meantime, an infrared sensor requests formation of pixels that allow for acquisition of parallax information making focus detection possible,

It is desirable to provide an imaging device and an electronic apparatus having a focus detection function.

An imaging device as an embodiment of the present disclosure includes: a pixel array part in which a plurality of pixels is disposed in a row direction and a column direction; a photoelectric conversion layer including a compound semiconductor; and an optical member in which a first refractive index portion and a second refractive index portion having mutually different refractive indices are disposed alternately from a central part to an outer peripheral part. The optical member is disposed on side of a light entering surface of the photoelectric conversion layer to straddle the plurality of pixels adjacent at least in the row direction or the column direction.

An electronic apparatus as an embodiment of the present disclosure includes the imaging device according to the embodiment of the present disclosure described above.

In the imaging device as the embodiment of the present disclosure and the electronic apparatus as the embodiment, in the pixel array part in which the plurality of pixels is disposed in the row direction and the column direction, the optical member is disposed on light entering side of the electric conversion layer including the compound semiconductor to straddle the plurality of pixels adjacent at least in the row direction or the column direction. In the optical member, the first refractive index portion and the second refractive index portion having mutually different refractive indices are disposed alternately from the central part to the outer peripheral part. Consequently, wavelengths passing through the optical member are focused at the photoelectric conversion layer.

### BRIEF DESCRIPTION OF DRAWINGS

FIG. 1 is a cross-sectional schematic diagram illustrating a configuration example of an imaging device according to an embodiment of the present disclosure.

FIG. 2 is a block diagram illustrating an overall configuration of the imaging device illustrated in FIG. 1.

FIG. 3 is a plan schematic diagram illustrating an example of layout of a Fresnel zone plate in the imaging device illustrated in FIG. 1.

FIG. 4 is a diagram explaining a light condensing principle of the Fresnel zone plate.

FIG. 5 is a diagram illustrating a distribution of incident angles of image plane phase difference pixels.

FIG. 6 is a plan schematic diagram lusts. g an example of an imaging device according to Modification Example 1 of the present disclosure.

FIG. 7 is a cross-sectional schematic diagram illustrating a configuration example of an imaging device according to Modification Example 2 of the present disclosure.

FIG. 8 is a cross-sectional schematic diagram illustrating a configuration example of an imaging device according to Modification Example 3 of the present disclosure.

FIG. 9 is a plan schematic diagram illustrating an example of layout of a light shielding film in a pixel part of the imaging device illustrated in FIG. 8.

FIG. 10 is a cross-sectional schematic diagram illustrating a configuration example of an imaging device according to Modification Example 4 of the present disclosure.

FIG. 11A is a plan schematic diagram illustrating an example of layout of a Fresnel zone plate in an imaging device according to Modification Example 5 of the present disclosure.

FIG. 11B is a plan schematic diagram illustrating another example of the layout of the Fresnel zone plate in the imaging device according to Modification Example 5 of the present disclosure.

FIG. 12A is a plan schematic diagram illustrating another example of the layout of the Fresnel zone plate in the imaging device according to Modification Example 5 of the present disclosure.

FIG. 12B is a plan schematic diagram illustrating another example of the layout of the Fresnel zone plate in the imaging device according to Modification Example 5 of the present disclosure.

FIG. 13A is a plan schematic diagram illustrating another example of the layout of the Fresnel zone plate in the imaging device according to Modification Example 5 of the present disclosure.

FIG. 13B is a plan schematic diagram illustrating another example of the layout of the Fresnel zone plate in the imaging device according to Modification Example 5 of the present disclosure.

FIG. 14A is a plan schematic diagram illustrating another example of the layout of the Fresnel zone plate in the imaging device according to Modification Example 5 of the present disclosure.

FIG. 14B is a plan schematic diagram illustrating another example of the layout of the Fresnel zone plate in the imaging device according to Modification Example 5 of the present disclosure.

FIG. 15 is a cross-sectional schematic diagram illustrating a configuration example of an imaging device according to Modification Example 6 of the present disclosure.

FIG. 16 is a schematic diagram illustrating another example of a Fresnel zone plate according to Modification Example 7 of the present disclosure.

FIG. 17 is a block diagram illustrating a configuration example of an electronic apparatus including the imaging device illustrated in FIG. 1 or the like.

FIG. 18 is a block diagram depicting an example of schematic configuration of a vehicle control system.

FIG. 19 is a diagram of assistance in explaining an example of installation positions of an outside-vehicle information detecting section and an imaging section.

### MODES FOR CARRYING OUT THE INVENTION

In the following, embodiments of the present disclosure are described in detail with reference to the drawings. The embodiments described below each illustrate a specific example of the present disclosure, and the present disclosure is not limited to the following embodiments. Moreover, the present disclosure is not limited to positions, dimensions, dimension ratios, and other factors of respective components illustrated in the drawings. It is to be noted that description is given in the following order:

1. Embodiment (Example of an imaging device including image plane phase difference pixels configured by disposing a Fresnel zone plate on light entering side)

### 2. Modification Examples

2.1. Modification Example 1 (Another example of a configuration of an imaging device)
2.2. Modification Example 2 (Another example of a configuration of an imaging device)
2.3. Modification Example 3 (Another example of a configuration of an imaging device)
2.4. Modification Example 4 (Another example of a configuration of an imaging device)
2.5. Modification Example 5 (Another example of layout of a Fresnel zone plate in a pixel part)
2.6. Modification Example(,mother example of a configuration of an imaging device)
2-7. Modification Example 7 (Another example of a plane configuration of the Fresnel zone plate)

### 3. Application Example

### 4. Practical Application Example

### 1. EMBODIMENT

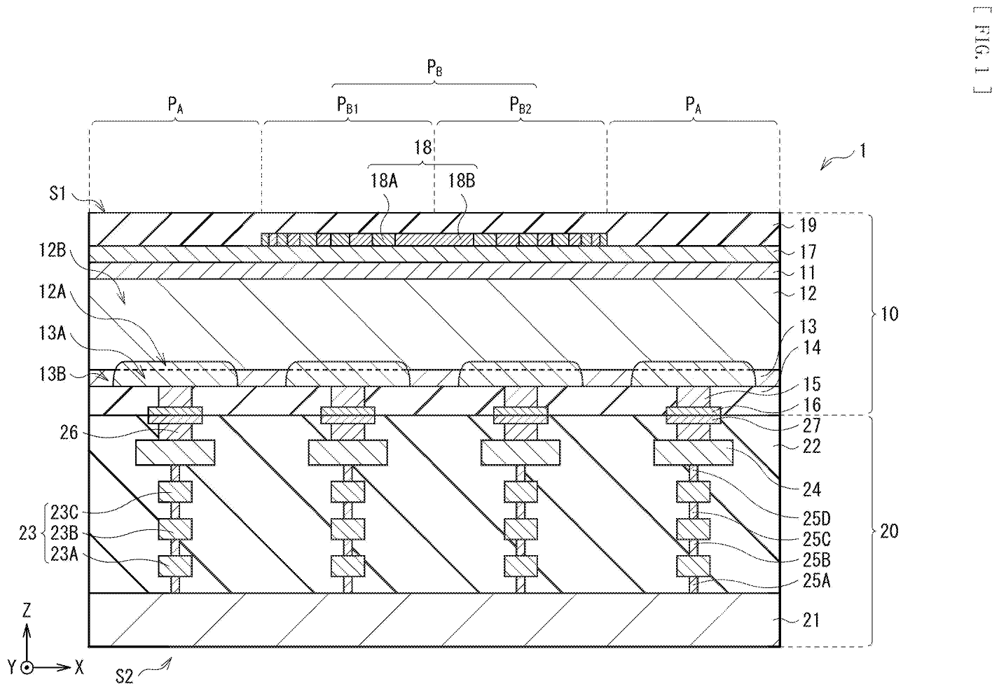

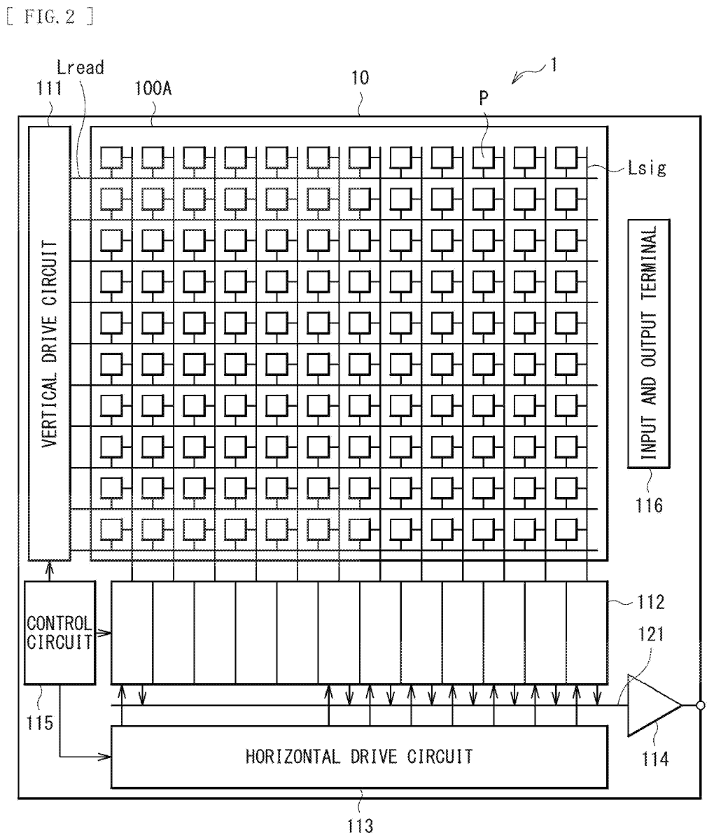

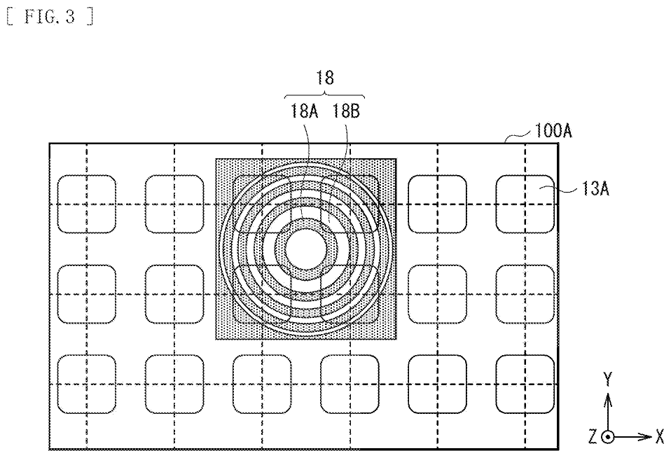

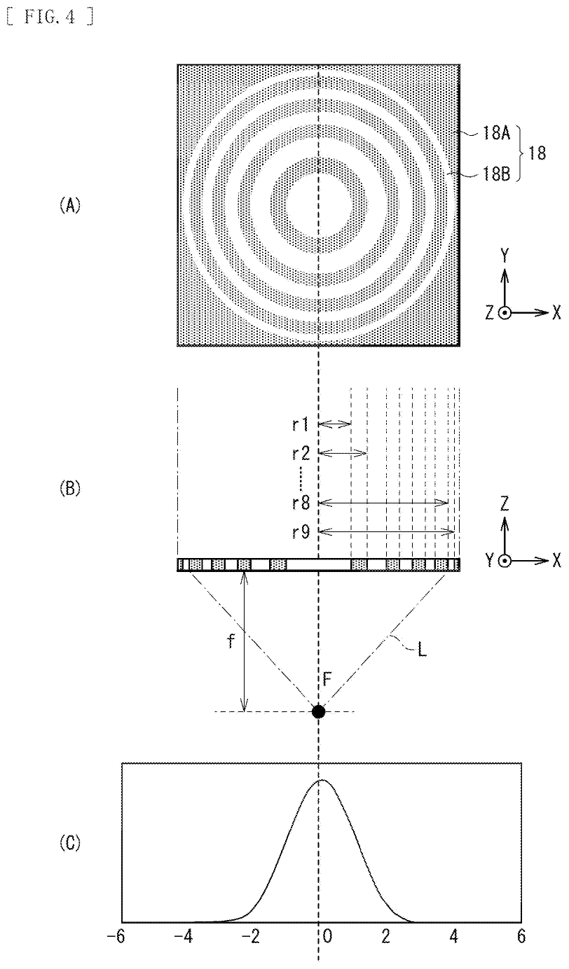

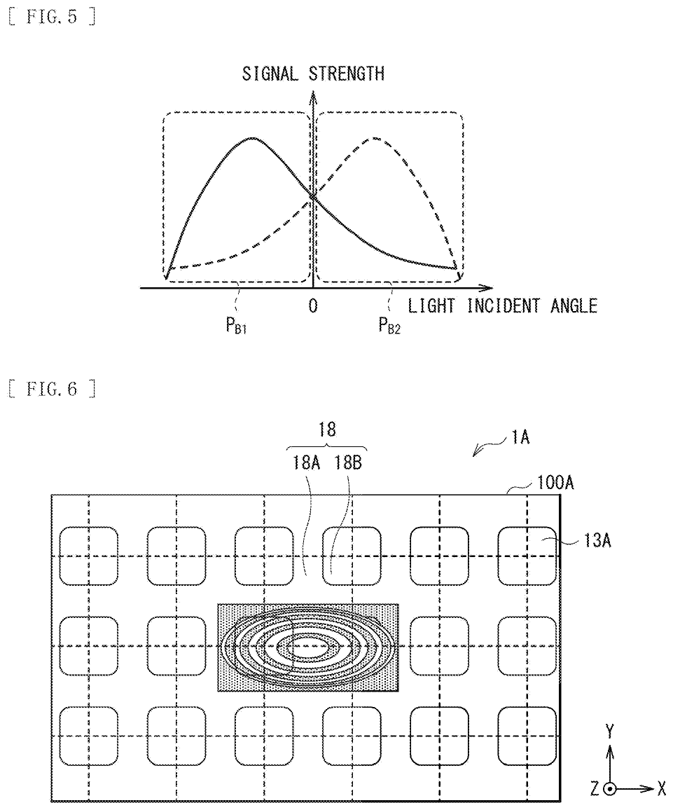

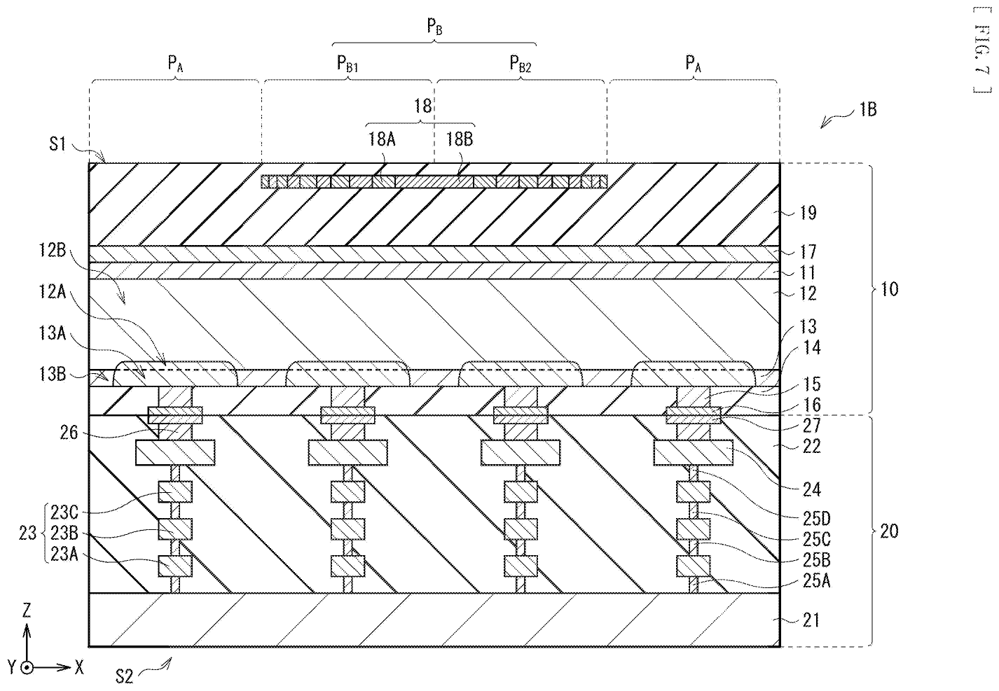

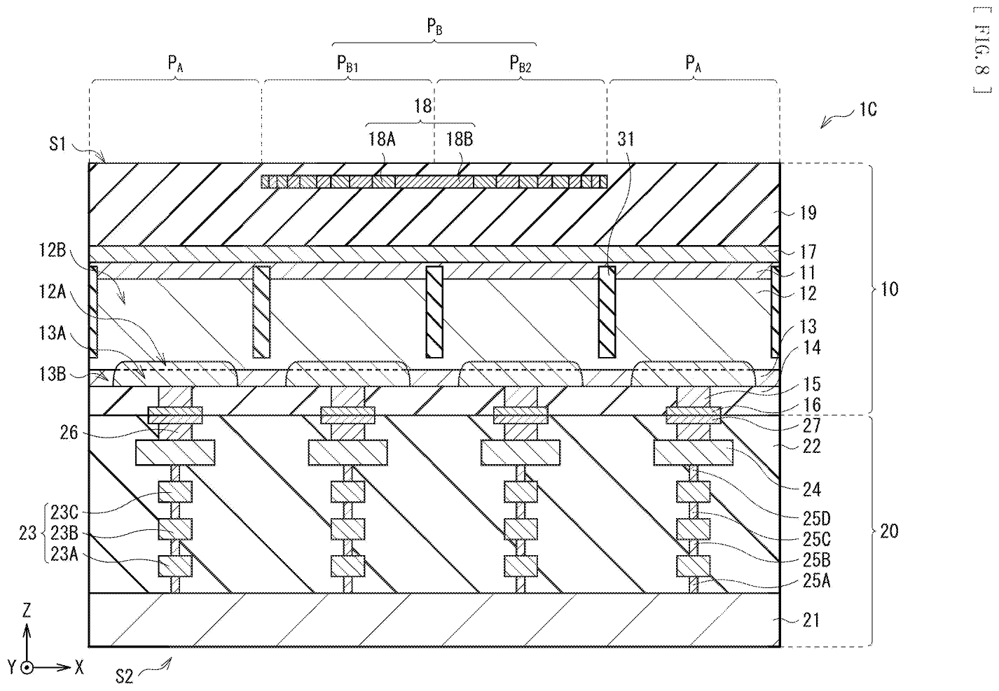

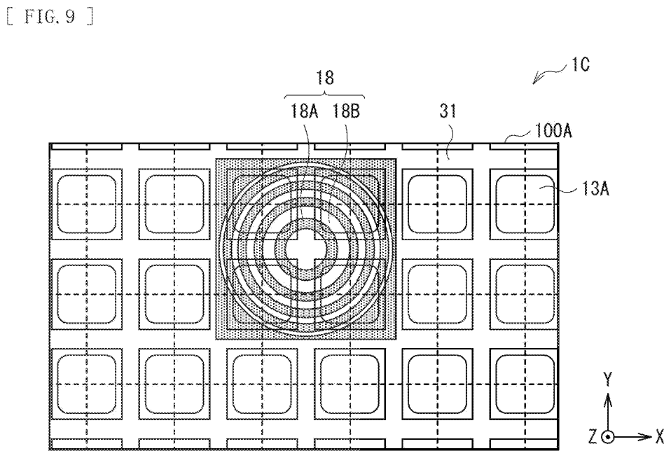

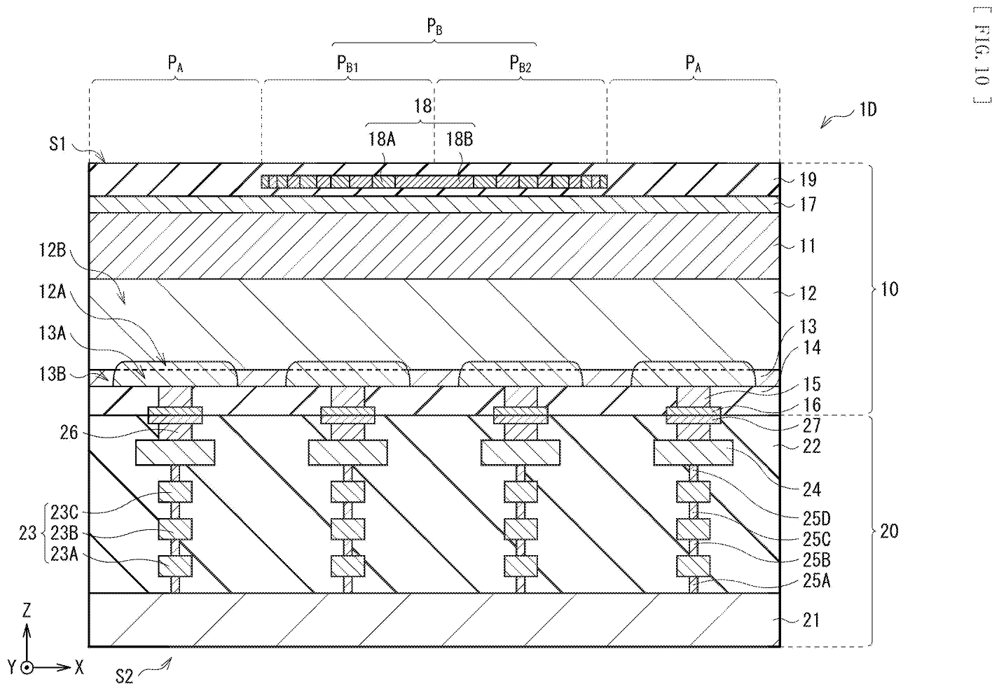

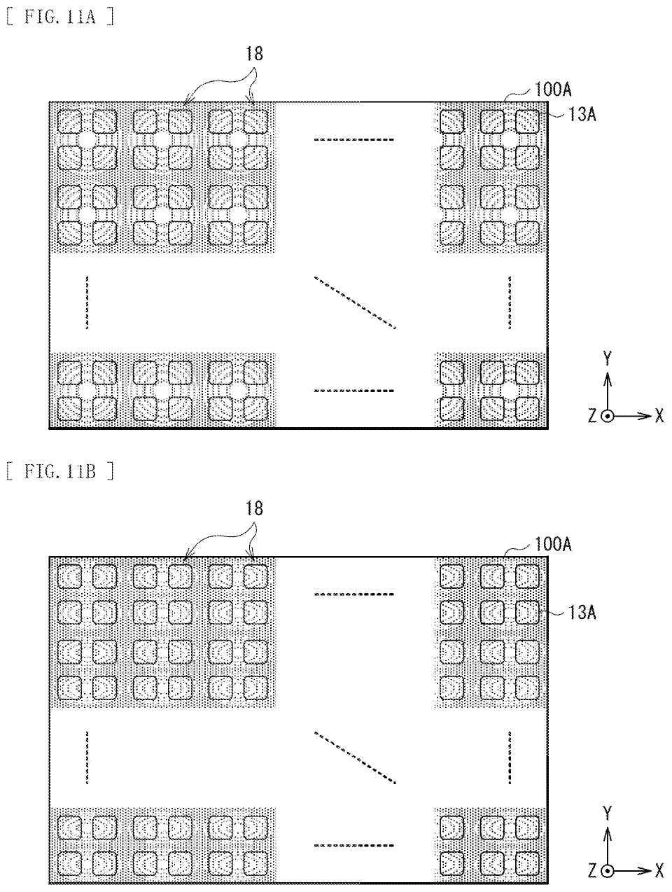

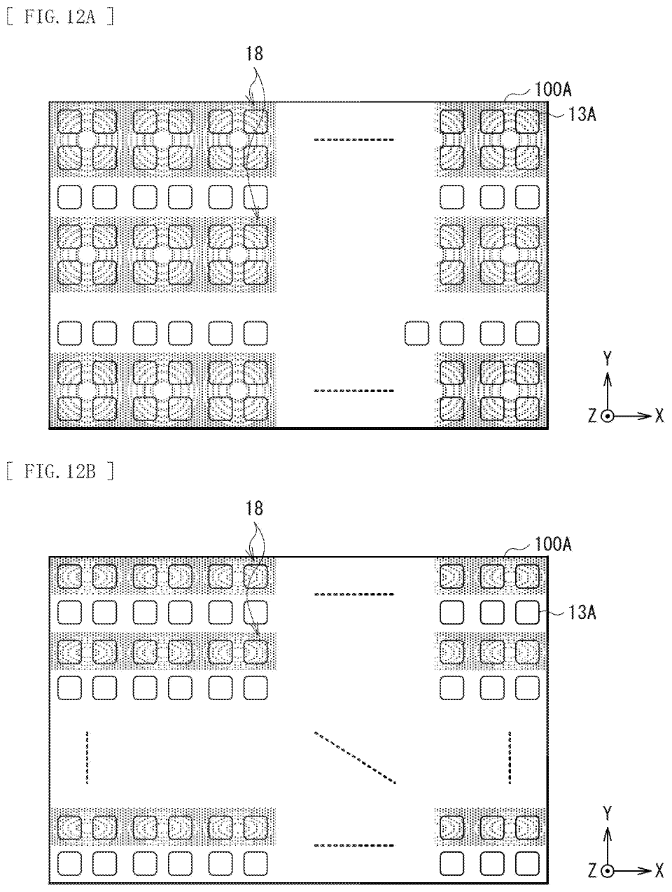

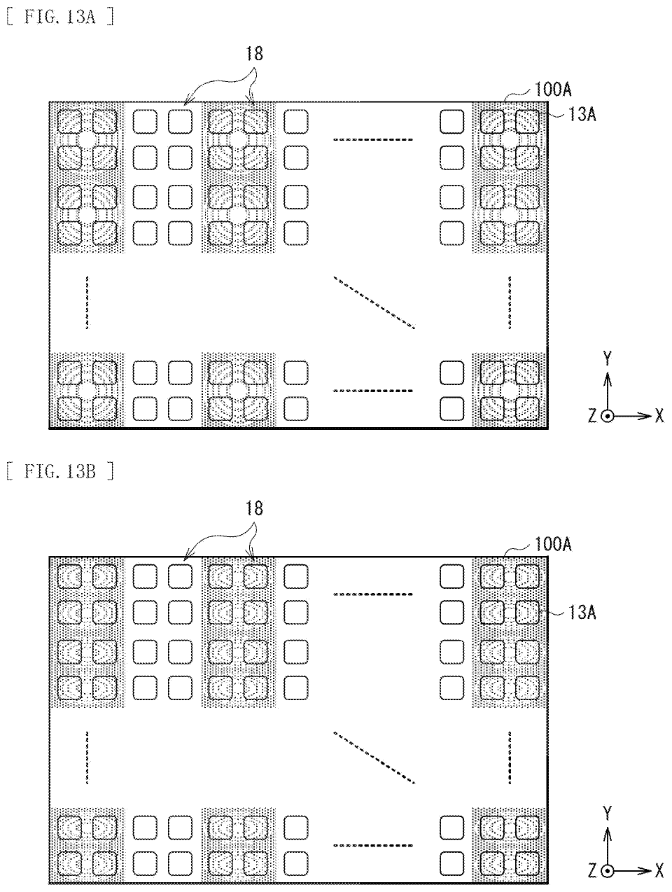

FIG. 1 schematically illustrates an example of a cross-sectional configuration of an imaging device (imaging device 1) according to an embodiment of the present disclosure. FIG. 2 illustrates an example of an overall configuration of the imaging device 1 illustrated in FIG. 1. The imaging device 1 is, for example, a CMOS (Complementary Metal Oxide Semiconductor) image sensor, etc., used in an electronic apparatus such as a digital still camera or a video camera. The imaging device 1 includes a pixel array part 100A, as an imaging area, in which a plurality of light receiving unit regions (referred to as unit pixels P) is two-dimensionally disposed in a matrix. The imaging device 1 has, for example, a photoelectric conversion function for wavelengths in a visible light region (from 380 nm or more to less than 780 nm, for example) to an infrared region (from 780 nm or more to less than 2400 nm, for example), and is applied to, for example, an infrared sensor, etc.

The imaging device 1 of the present embodiment includes pixels (imaging pixels P_{A}) that are able to acquire imaging information, and pixels (image plane phase difference pixels P_{B}) that are able to acquire parallax information. In the imaging device 1 of the present embodiment, a Fresnel zone plate 18 is disposed to straddle the plurality of unit pixels P, which configures the image plane phase difference pixels P_{B}.

### [Outline Configuration of Imaging Device]

The imaging device 1 captures entering light (image light) from a subject via an optical lens system (not illustrated), converts a light amount of the entering light imaged on an imaging surface, into an electric signal for each pixel, and outputs the electric signal as a pixel signal. The imaging device 1 includes the pixel array part 100A as the imaging area on a device substrate 10 and includes, for example, a vertical drive circuit 111, a column signal processing circuit 112, a horizontal drive circuit 113, an output circuit 114, a control circuit 115, and an input and output terminal 116 in a region around this pixel array part 100A.

In the pixel array part 100A, for example, the plurality of unit pixels P is two-dimensionally disposed in a matrix. To each of the unit pixels P, for example, each of pixel drive lines Lread (specifically a row selection line and a reset control line) is wired for each of pixel rows, and each of vertical signal lines Lsig is wired for each of pixel columns. The pixel drive lines Lread transmit drive signals for reading out signals from the unit pixels P. One end of the pixel drive line Lread is coupled to an output end corresponding to each row of the vertical drive circuit 111.

The vertical drive circuit 111 is a pixel drive unit that includes a shift register, an address decoder, etc., and drives each of the unit pixels of the pixel array part 100A for each row, for example. A signal outputted from each of the unit pixels P on a pixel row selectively scanned by the vertical drive circuit 11. is supplied to the column signal processing circuit 112 through each of the vertical signal lines Lsig. The column signal processing circuit 112 includes an amplifier, a horizontal selection switch, etc. provided on each of the vertical signal lines Lsig.

The horizontal drive circuit 113 includes a shift register, an address decoder, etc., and drives each of the horizontal selection switches of the column signal processing circuit 112, in order, while scanning the horizontal selection switches. As a result of the selective scanning by the horizontal drive circuit 113, the signal of each pixel transmitted through each of the vertical signal lines Lsig is outputted to a horizontal signal line 121 in order and transmitted to outside of the device substrate 10 through the horizontal signal line 121.

The output circuit 114 performs signal processing on the signal sequentially supplied from each column signal processing circuit 112 via the horizontal signal line 121 and outputs the signal. The output circuit 114 may perform only buffering, for example, or may perform black level adjustment, column variation correction, various digital signal processing, and the like.

Circuit parts including the vertical drive circuit 111, the column signal processing circuit 112, the horizontal drive circuit 113, the horizontal signal line 121, and the output circuit 114 may be formed directly on the device substrate 10 or a readout circuit substrate 20, or placed on an external control IC. Alternatively, those circuit parts may be formed on another substrate coupled by a cable, etc.

The control circuit 115 receives a clock given from the outside of the device substrate 10, data for an instruction about an operation mode, and the like, and also outputs data such as internal information of the imaging device 1. The control circuit 115 further includes a timing generator that generates various types of timing signals, and performs drive control of peripheral circuits such as the vertical drive circuit 111, the column signal processing circuit 112, and the horizontal drive circuit 113 on the basis of the various types of timing signals generated by the timing generator.

The input and output terminal 116 exchanges a signal with the outside.

### [Unit Pixel Configuration]

FIG. 3 schematically illustrates an example of planar layout of the Fresnel zone plate 18 in the pixel array part 100A in the imaging device 1 illustrated in FIG. 1. The imaging device 1 is an imaging device of backside illumination-type, for example. As described above, the imaging device 1 includes the imaging pixels P_{A} and the image plane phase difference pixels P_{B}. For example, the image plane phase difference pixels P_{B} are discretely disposed on the pixel array part 100A in which the plurality of imaging pixels P_{A} is disposed in a matrix. The imaging pixel P_{A} includes one of the unit pixels P, and the image plane phase difference pixels P_{B} include four of the unit pixels P that are adjacent in, for example, a row direction (X-axis direction) and a column direction (Y-axis direction) (two rows×two columns).

The imaging pixels P_{A} and the image plane phase difference pixels P_{B} each have a configuration in which the device substrate 10 and the readout circuit substrate 20 are stacked, the readout circuit substrate 20 being provided on side opposite to a light entering side S1 of a semiconductor substrate 11. In the following, description is given of a configuration of each unit.

The device substrate 10 includes the semiconductor substrate 11, a photoelectric conversion layer 12, a gap layer 13, and a protective layer 14. The photoelectric conversion layer 12, the gap layer 13, and the protective layer 14 are stacked in this order on a surface (readout circuit substrate side S2) opposite to the light entering side S1 of the semiconductor substrate 11. A contact electrode 15 is provided on the protective layer 14, the contact electrode 15 being electrically coupled to a selective region (first conductive type region 13A) of the gap layer 13. The device substrate 10 further includes an electrode layer 17, the Fresnel zone plate 18, and a protective layer 19. The electrode layer 17 and the protective layer 19 are stacked in this order on the light entering side SI of the semiconductor substrate 11. The Fresnel zone plate 18 is embedded and formed on side of the electrode layer 17 of the protective layer 19, for example.

The semiconductor substrate 11 includes, for example, a group III-V semiconductor of n-type or i-type (intrinsic semiconductor). In the imaging device 1, although the photoelectric conversion layer 12 is formed in contact with the surface on the readout circuit substrate side S2 of the semiconductor substrate 11, another layer may be interposed between the semiconductor substrate 11 and the photoelectric conversion layer 12. Although examples of materials of the layer interposed between the semiconductor substrate 11 and the photoelectric conversion layer 12 include a compound semiconductor such as InAlAs, Ge, Si, GaAs, InP, InGaAsP, or AlGaAs, it is desirable that a material lattice-matched with the semiconductor substrate 11 and the photoelectric conversion layer 12 be selected.

The photoelectric conversion layer 12 includes a compound semiconductor that absorbs, for example, wavelengths in the infrared region (hereinafter referred to as infrared rays) and generates electric charges (electrons and holes). Here, the photoelectric conversion layer 12 is continuously provided on the semiconductor substrate 11 as a common layer to the plurality of unit pixels P (imaging pixels P_{A} and image plane phase difference pixels P_{B}).

The compound semiconductor used in the photoelectric conversion layer 12 is, for example, a group III-V semiconductor and examples of the compound semiconductor include InₓGa₍₁₋ₓ₎As (x: 0<x≤1). However, in order to obtain higher sensitivity in the infrared region, it is desirable that x≥0.4. For example, an example of composition of the compound semiconductor of the photoelectric conversion layer 12 lattice-matched with the semiconductor substrate 11 including InP is In_{0.53}Ga_{0.47}As.

The photoelectric conversion layer 12 has a pn junction or a pin junction formed by stacking a first conductive type region 12A and a region (second conductive type region 12B) other than the first conductive type region 12A to be described below. The second conductive type region 12B formed inside the photoelectric conversion layer 12 is a region containing n-type impurities, for example. Examples of the n-type impurities include silicon (Si), and the like. However, the second conductive type region 12B may include an intrinsic semiconductor (may be a semiconductor region of the i-type).

It is desirable that the gap layer 13, to be described below in detail, have a role of electrically isolating adjacent unit pixels P or suppressing generation of a dark current. It is preferable to form the gap layer 13 including a compound semiconductor that has a bandgap larger than the bandgap of the photoelectric conversion layer 12. Examples of the compound semiconductors with the bandgap larger than In_{0.53}Ga_{0.47}As (bandgap of 0.74 eV) include InP (bandgap of 1.34 eV), InAlAs, and the like. It is to be noted that a layer including a semiconductor such as any of InAlAs, Ge, Si, GaAs, InP, etc. may be further interposed between the gap layer 13 and the photoelectric conversion layer 12.

The first conductive type region 13A is formed in a selective region of the gap layer 13. The first conductive type region 13A is formed for each of the unit pixels P. In other words, a plurality of the first conductive type regions 13A is formed discretely from each other in the gap layer 13.

The first conductive type region 13A is a region containing p-type impurities (p-type impurity region) for example. Examples of the p-type impurities include zinc (Zn). The first conductive type region 13A extends to a position of a predetermined depth from side opposed to the readout circuit substrate 20 of the gap layer 13, and, for example, partly extends to inside of the photoelectric conversion layer 12, as illustrated in FIG. 1. The first conductive type region 13A extending to the inside of this photoelectric conversion layer 12 is the first conductive type region 12A in the foregoing photoelectric conversion layer 12. A second conductive type region 13B is formed adjacent to the first conductive type region 13A around the first conductive type region 13A. It is to be noted that the p-type impurity region forming the first conductive type region 13A does not necessarily have to extend to the photoelectric conversion layer 12. A boundary of the p-type impurity region may match an interface between the gap layer 13 and the photoelectric conversion layer 12 or may be formed within a layer of the gap layer 13.

In the gap layer 13, a pn junction interface is formed at a boundary between these first conductive type region 13A and second conductive type region 13B. This electrically isolates the adjacent unit pixels P from each other.

The protective layer 14 is formed by using an inorganic insulating material, for example. Examples of the inorganic insulating materials include silicon nitride (SiN), aluminum oxide (Al₂O₃), silicon oxide (SiO₂), and hafnium oxide (HfO₂). The protective layer 14 includes one or more types of these.

The contact electrode 15 is an electrode supplied with a voltage for reading out the electric charges (holes, for example) generated in the photoelectric conversion layer 12, and is formed for each of the unit pixels P, for example. Examples of constituent materials of the contact electrode 15 include any simple substance of or an alloy containing one or more types of: titanium (Ti), tungsten (W), titanium nitride (TiN), platinum (Pt), gold (Au), germanium (Ge), palladium (Pd), zinc (Zn), nickel (Ni), or aluminum (Al). The contact electrode 15 may be a single layer film including the foregoing constituent materials, or may be formed as a laminated film in hick two or more types, for example, are combined.

The contact electrode 15 is electrically coupled to the first conductive type region 12A of the photoelectric conversion layer 12 via the first conductive type region 13A. It is to be noted that the contact electrode 15 may be formed one by one for each one of the unit pixels P, or a plurality of the contact electrodes 15 may be provided for each one of the unit pixels P. In a case where the plurality of contact electrodes 15 is disposed for each one of the unit pixels P, some of the contact electrodes 15 may be electrodes (dummy electrodes) that do not contribute to charge extraction.

A connection layer 16 wider than, for example, the contact electrode 15 is provided on the contact electrode 15. In other words, the connection layer 16 is formed like an cave on an upper part of the contact electrode 15. The connection layer 16 is exposed to a surface opposed to the readout circuit substrate 20 of the protective layer 14, and is intended to electrically couple the device substrate 10 and the readout circuit substrate 20.

Similarly to the photoelectric conversion layer 12, for example, the electrode layer 17 is continuously provided on the semiconductor substrate 11 as a common layer to the plurality of unit pixels P (imaging pixels P_{A} and the image plane phase difference pixels P_{B}). Of the electric charges generated in the photoelectric conversion layer 12, in a case where the holes, for example, are read out as signal charges through the contact electrode 15, electrons are discharged through the electrode layer 17.

The electrode layer 17 is formed using a conductive material having optical transparency. Examples of constituent materials of the electrode layer 17 include indium tin oxide (ITO), tin (Sn), tin oxide (SnO₂), IWO, indium-zinc composite oxide (IZO), zinc-doped aluminum oxide (AZO), zinc-doped gallium oxide (GZO), magnesium- and zinc-doped aluminum oxide (AlMgZnO), indium-gallium composite oxide (IGO), In—GaZnO₄ (IGZO), fluorine-doped indium oxide (IFO), antimony-doped tin oxide (ATO), fluorine-doped tin oxide (FTO), zinc oxide (ZnO), boron-doped ZnO, InSnZnO, etc. In a case where the imaging device 1 is used as the infrared sensor, in particular, it is preferable to use indium titanium oxide (ITiO) having high transparency to the infrared region.

The Fresnel zone plate 18 utilizes a photorefractive phenomenon to cause, for example, the infrared rays to diffract and focus. The Fresnel zone plate 18 corresponds to a specific example of an “optical member” of the present disclosure including a first refractive index portion and a second refractive index portion having mutually different refractive indices. FIG. 4 is a diagram explaining a light condensing principle of the Fresnel zone plate 18.

The Fresnel zone plate 18 includes a light shielding zone 18A corresponding to the first refractive index portion and a light transmitting zone 18B corresponding to the second refractive index portion, the light shielding zone 18A and the light transmitting zone 18B being disposed alternately in a substantially concentric circle pattern, as illustrated in (A) of FIG. 4, for example. In the Fresnel zone plate 18, spacing between the light shielding zone 18A and the light transmitting zone 18B becomes narrower toward the outer periphery. More specifically, as illustrated in the following mathematical expression (1), the boundary between the light shielding zone 18A and the light transmitting zone 18B is formed so that an optical path difference from the boundary between the light shielding zone 18A and the light transmitting zone 18B to a focal point F is, for example, an integral multiple of a half wavelength of infrared rays. Consequently, as illustrated in (B) of FIG. 4, a wavelength L that has entered each of the zones 18A and 18B in the outer periphery is bent more greatly and focused at the focal point F. At the focal point F, the wavelengths diffracted at all zone boundaries strengthen each other by interference, as illustrated in (C) of FIG. 4.

$$\begin{matrix}[ Math . 1 ] & \\ \sqrt{{f}^{2} + {r}_{n}^{2}} = f + \frac{n λ}{2} & ( 1 )\end{matrix}$$

(f: Focal length, r: zone boundary radius, λ: wavelength, and n: integer)

Table 1 summarizes an example of parameters of the Fresnel zone plate 18 in a case where a size of the unit pixel P is 5 μm square, a film thickness of the protective layer 19 is 20 nm, the film thickness of the electrode layer 17 is 40 nm, the film thickness of the semiconductor substrate 11 is 20 nm, and the film thickness of the photoelectric conversion layer 12 is 4 μm. The zone plate 18 is provided to straddle the adjacent four unit pixels P in the row direction (X-axis direction) and the column direction (Y-axis direction), as illustrated in FIG. 3, for example. These four unit pixels P configure the image plane phase difference pixels P_{B}. The Fresnel zone plate 18 is disposed at 10 μm square with respect to these four unit pixels P. FIG. 5 illustrates a strength distribution for an incident angle of a unit pixel P_{B1} on the left side of a paper surface and a unit pixel P_{B2} on the right side of the paper surface among the four unit pixels P in which the Fresnel zone plate is disposed.

TABLE 1

| | | λ | f | rₙ |
|---|---|---|---|---|
| | n | (μm) | (μm) | (μm) |
| r1 | 1 | 1.5 | 4 | 2.6 |
| r2 | 2 | 1.5 | 4 | 3.8 |
| r3 | 3 | 1.5 | 4 | 4.8 |
| r4 | 4 | 1.5 | 4 | 5.7 |
| r5 | 5 | 1.5 | 4 | 6.6 |
| r6 | 6 | 1.5 | 4 | 7.5 |
| r7 | 7 | 1.5 | 4 | 8.3 |
| r8 | 8 | 1.5 | 4 | 9.2 |

It is possible to form the light shielding zone 18A using titanium (Ti), tungsten (W), carbon (C), chromium oxide (Cr₂O₃), an alloy of samarium (Sm) and silver (Ag), organic material, etc. it is possible to form the light transmitting zone 18B using silicon oxide (SiOₓ), silicon nitride (SiNₓ), or the like, for example. In addition to this, the light transmitting zone 18B may be formed by an air gap.

The protective layer 19 is designed to flatten a surface of the light entering side S1 of the imaging device 1, and formed using an inorganic insulating material, similarly to the protective layer 14, for example. Examples of the inorganic insulating materials include silicon nitride (SINₓ), silicon oxide (SiOₓ), aluminum oxide (Al₂O₃), and hafnium oxide (HfO₂). The protective layer 19 includes one or more types of these

The readout circuit substrate 20 includes a support substrate 21 including Si, for example, an interlayer insulation layer 22, a wiring layer 23, and a pixel circuit 24. The wiring layer 23 and the pixel circuit 24 are designed to perform reading of a signal from each of the unit pixels P. The wiring layer 23 includes a plurality of various types of wires 23A, 23B, and 23C. The pixel circuit 24 and the various types of wires 23A, 23B, and 23C are electrically coupled to each other by through electrodes 25A, 25B, 25C, and 25D. A readout electrode 26 is provided on the pixel circuit 24. Similarly to the contact electrode 15, a connection layer 27 formed like an eave, for example, is formed on the readout electrode 26. By the connection layer 27 and the connection layer 16 on the side of the device substrate 10 being joined, the readout electrode 26 is electrically coupled with the contact electrode 15. This makes it possible to read out the signal charge generated in the photoelectric conversion layer 12 for each of the unit pixels P.

### [Workings and Effects]

In the imaging device 1 of the present embodiment, the Fresnel zone plate 18 is disposed to straddle the four unit pixels P adjacent in the row direction and the column direction in the pixel array part 100A in which the plurality of unit pixels P is disposed in the row direction and the column direction. In the Fresnel zone plate 18, the light shielding zone 18A and the light transmitting zone 18B are disposed alternately in a substantially concentric circle pattern. As a result, wavelengths (infrared rays, for example) that have entered the Fresnel zone plate 18 are diffracted at the zone boundary between the light shielding zone 18A and the light transmitting zone 18B and focused at a predetermined position. This will be described below.

In recent years, a semiconductor imaging device (imaging device) with a focus detection function based on a phase difference detection method has become widespread. In such an imaging device, each of pixels includes a plurality of photodiodes (PDs), and by one on-chip lens being shared by the plurality of PDs, it is possible to acquire the parallax information.

However, infrared rays such as short-wavelength infrared rays classified into a wavelength region of 0.9 μm to 1.7 μm, for example, have a smaller refractive index than visible light. Therefore, the on-chip lens has a weak light-condensing capability, and an increase in a thickness of the on-chip lens is requested in an attempt to obtain a light-condensing effect similar to the fight-condensing effect of the visible light, which makes manufacturing difficult.

In contrast to this, in the imaging device 1 of the present embodiment, the Fresnel zone plate 18 in which the light shielding zones 18A and the light transmitting zones 18B are disposed alternately in a substantially concentric circle pattern is disposed for the four unit pixels P adjacent in the row direction and the column direction. As a result, for example, the short-wavelength infrared rays that have entered the Fresnel zone plate 18 are diffracted at the zone boundary between the light shielding zones 18A and the light transmitting zones 18B and focused at a desired position (within the photoelectric conversion layer 12). Therefore, it becomes possible to obtain the strength distribution for the incident angle as illustrated in FIG, 5, in the left and right unit pixels P (unit pixel P_{B1} and unit pixel P_{B2}) in which the Fresnel zone plate 18 is disposed. That is, the image plane phase difference pixel P_{B}, which is able to acquire the parallax information for the short-wavelength infrared rays, is formed.

As described above, in the imaging device 1 of the present embodiment, it becomes possible to provide the infrared sensor including the image plane phase difference pixel P_{B}, which is able to acquire the parallax information, and having the focus detection function.

Next, description is given of Modification Examples 1 to 7, an application example, and a practical application example of the present disclosure. In the following, components similar to the components of the foregoing embodiment are denoted by the same reference numerals, and description thereof is omitted where appropriate.

### 2. MODIFICATION EXAMPLES

### 2-1. Modification Example 1

FIG. 6 schematically illustrates an example of a planar configuration of an imaging device (imaging device 1A) according to Modification Example 1 of the present disclosure. The imaging device 1A is, for example, the CMOS image sensor, etc., used in the electronic apparatus such as the digital still camera, the video camera, etc. Similarly to the imaging device 1 in the foregoing embodiment, the imaging device 1A is applied to, for example, the infrared sensor, etc.

Although in the foregoing embodiment, the example is illustrated in which the one Fresnel zone plate 18 is disposed for the four unit pixels P and these four unit pixels P configure the image plane phase difference pixel P_{B}, the present disclosure is not limited to this. For example, as illustrated in FIG. 6, the Fresnel zone plate 18 having a size of 10 μm×5 μm, for example, may be disposed to straddle two unit pixels P adjacent, for example, in the row direction (X-axis direction), and these two unit pixels P may configure the image plane phase difference pixel P_{B}.

Also in such a configuration, similarly to the foregoing embodiment, in the left and right unit pixels P in which the Fresnel zone plate 18 is disposed, the strength distribution for the incident angle as illustrated in FIG. 5 is obtained. That is, it becomes possible to provide the infrared sensor including the image plane phase difference pixel P_{B}, which is able to acquire the parallax information, and having the focus detection function.

### 2-2. Modification Example 2

FIG. 7 schematically illustrates an example of a cross-sectional configuration of an imaging device (imaging device 1B) according to Modification Example 2 of the present disclosure. The imaging device 1B is, for example, the CMOS image sensor, etc., used in the electronic apparatus such as the digital still camera, the video camera, etc. Similarly to the imaging device 1 in the foregoing embodiment, the imaging device 1B is applied to, for example, the infrared sensor, etc.

In this modification example, spacing between the Fresnel zone plate 18 and the photoelectric conversion layer 12 corresponding to the focal length is secured, by increasing a film thickness of the protective layer 19 in a stacking direction (Z-axis direction) to the same extent as the focal length of the Fresnel zone plate 18, for example, and embedding the Fresnel zone plate 18 inside the protective layer 19. This makes it possible to improve phase difference separability in the image plane phase difference pixel P_{B} as compared with the foregoing embodiment.

### 2-3. Modification Example 3

FIG. 8 schematically illustrates an example of a cross-sectional configuration of an imaging device (imaging device 1C) according to Modification Example 3 of the present disclosure. FIG. 9 schematically illustrates a planar configuration of the imaging device 1C illustrated in FIG. 8. The imaging device 1C is, for example, the CMOS image sensor, etc., used in the electronic apparatus such as the digital still camera, the video camera, etc. Similarly to the imaging device 1 in the foregoing embodiment, the imaging device 1C is applied to, for example, the infrared sensor, etc.

In this modification example, a light shielding film 31 is provided between the unit pixels P adjacent in the row direction (X-axis direction) and the column direction (Y-axis direction). Specifically, the light shielding film 31 is provided around the unit pixels P and provided in a lattice pattern, for example, in the pixel array part 100A. The light shielding film 31 is embedded and formed continuously in, for example, the semiconductor substrate 11 and the photoelectric conversion layer 12. It is to be noted that a position to form the light shielding film 31 is not limited to this. For example, the light shielding film 31 may be formed only in the photoelectric conversion layer 12, or may penetrate the semiconductor substrate 11 and the photoelectric conversion layer 12 from the side of the light entering surface S1 to the readout circuit substrate side S2.

Examples of the constituent materials of the light shielding film 31 include titanium (Ti), tungsten (W), carbon (C), chromium oxide (Cr₂O₃), an alloy of samarium (Sm) and silver (Ag), an organic material, etc. The light shielding film 31 is configured as a single layer film or a laminated film including these materials. Specific examples of laminated films include a metal laminated film such as Ti/W.

As described above, in the imaging device 1C of this modification example, color mixture from the adjacent unit pixels P is reduced, which makes it possible to further improve the phase difference separability in the image plane phase difference pixel P_{B}, as compared with Modification Example 2 described above.

### 2-4. Modification Example 4

FIG. 10 schematically illustrates an example of a cross-sectional configuration of an imaging device (imaging device 1D) according to Modification Example 4 of the present disclosure. The imaging device 1D is, for example, the CMOS image sensor, etc., used in the electronic apparatus such as the digital still camera, the video camera, etc. Similarly to the imaging device 1 in the foregoing embodiment, the imaging device 1D is applied to, for example, the infrared sensor, etc.

Although in Modification Example 2 described above, the example is illustrated in which the film thickness of protective layer 19 is increased to secure the spacing between the Fresnel zone plate 18 and the photoelectric conversion layer 12 corresponding to the focal length, the present disclosure is not limited to this. For example, as illustrated in FIG. 10, the film thickness of the semiconductor substrate 11 in the stacking direction may be increased to the same extent as the focal length of the Fresnel zone plate 18 to secure the spacing between the Fresnel zone plate 18 and the photoelectric conversion layer 12 corresponding to the focal length. Also in such a configuration, it is possible to obtain effects similar to the effects of Modification Example 2 described above.

### 2-5. Modification Example 5

FIG. 11A to FIG. 14B schematically illustrate other examples of layout of the Fresnel zone plate 18 in the pixel array part 100A in the imaging device 1 as modification examples of the foregoing embodiment and Modification Example 1. Although in the foregoing embodiment, etc. are illustrated the examples in which the image plane phase different pixels P_{B} are disposed discretely in the pixel array part 100A in which the plurality of imaging pixels P_{A} is disposed in a matrix, in other words, the example in which the Fresnel zone plates 18 are disposed discretely in the pixel array part 100A, the present disclosure is not limited to this.

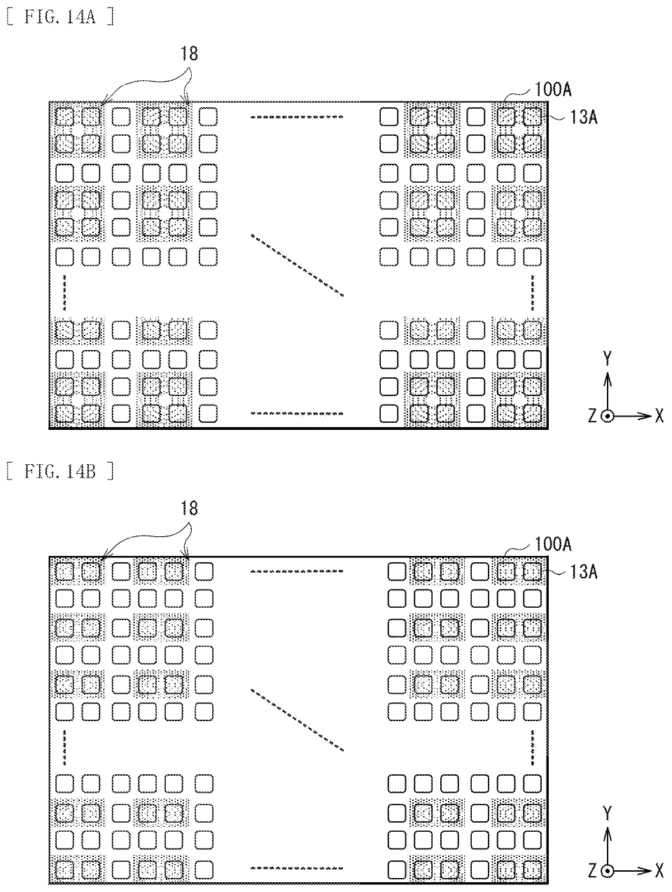

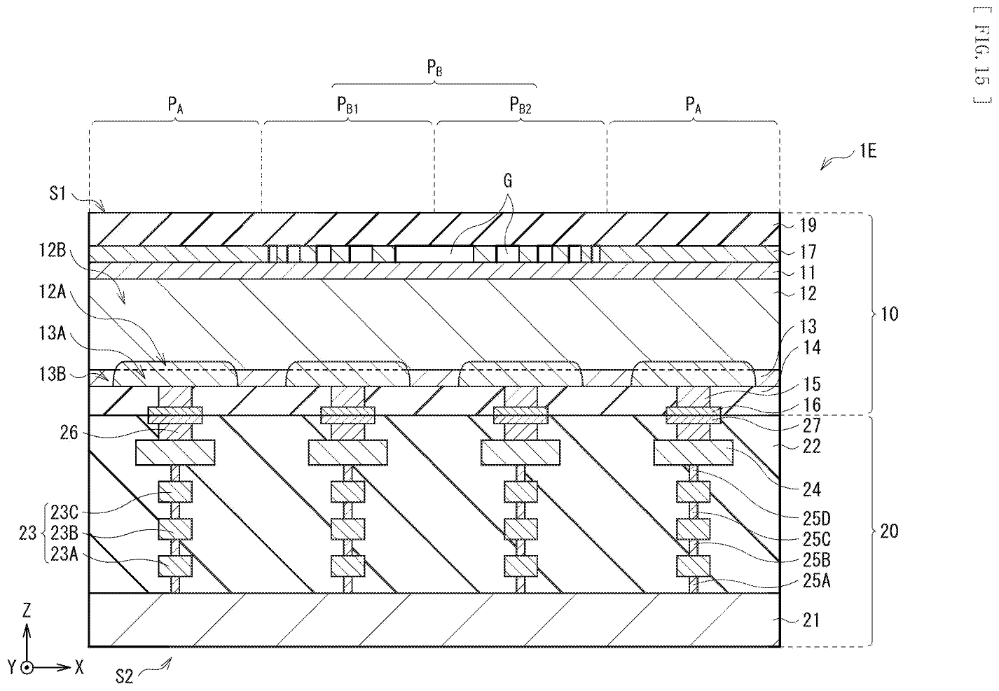

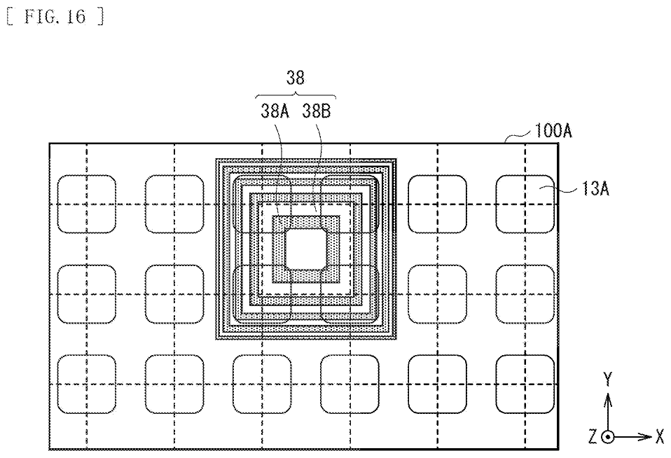

As illustrated in FIG. 11A and FIG. 11B, for example, the Fresnel zone plates 18 may be disposed over an entire region of the pixel array part 100A. As illustrated in FIG. 12A and FIG. 12B, for example, in the pixel array part 100A in which the plurality of imaging pixels P_{A} is two-dimensionally disposed in a matrix, the Fresnel zone plates 18 may be disposed continuously, for example, in the row direction (X-axis direction), and at substantially equal intervals, for example, in the column direction (Y-axis direction). As illustrated in FIG. 13A and FIG. 13B, for example, in the pixel array part 100A in which the plurality of imaging pixels P_{A} is two-dimensionally disposed in a matrix, the Fresnel zone plates 18 may be disposed continuously, for example, in the column direction (Y-axis direction) and at substantially equal intervals, for example, in the row direction (X-axis direction). Alternatively, as illustrated in FIG. 14A and FIG. 14B, for example, in the pixel array part 100A in which the plurality of imaging pixels P_{A} is two-dimensionally disposed in a matrix, the Fresnel zone plates 18 may be disposed, for example, in the lattice pattern, at substantially equal intervals.

### 2-6. Modification Example 6

FIG. 15 schematically illustrates an example of a cross-sectional configuration of an imaging device (imaging device 1E) according to Modification Example 6 of the present disclosure. The imaging device 1E is, for example, the CMOS image sensor, etc., used in the electronic apparatus such as the digital still camera, the video camera, etc. Similarly to the imaging device 1 in the foregoing embodiment, the imaging device 1E is applied to, for example, the infrared sensor, etc.

The “optical member” of the present disclosure may include a member other than the Fresnel zone plate 18. For example, the “optical member” of the present disclosure may have a configuration of the processed electrode layer 17. Specifically, by processing the electrode layer 17 to provide an air gap G similar to the light transmitting zone 18B of the Fresnel zone plate 18, for example, the wavelengths that have entered the electrode layer 17 are diffracted at the boundary between the electrode layer 17 and the air gap G and focused at the predetermined position.

The configuration described above corresponds to a so-called graded index lens. Description is given with a SWLL (Sub-Wave Length Lens) as an example, the SWLL being a type of the graded index lens. In a case where high refractive index portions and low refractive index portions are disposed alternately in a concentric circle pattern in a lateral direction of the optical member, if a cycle of the wavelengths is to the same extent as or smaller than a wavelength order of the entering light, wave fronts in the low refractive index portions and wave fronts in the high refractive index portions are coupled due to continuity of a wave motion equation, and an entire equiphase surface is curved to function as a convex lens having light condensing properties. In addition, an effective refractive index sensed by light is determined by a volume ratio of the high refractive index portions and the low refractive index portions within the cycle. Increasing the volume ratio of the low refractive index portions from a center of a concentric circle to an outer peripheral part contrarily reduces the effective refractive index to form the convex lens. That is, it is possible to change a curvature of the equiphase surface depending on the varying volume ratio of these high refractive index portions and low refractive index portions, thus allowing a focal position to be varied.

As described above, the imaging device 1E of this modification example makes it possible to obtain effects similar to the effects of the foregoing embodiment.

### 2-7. Modification Example 7

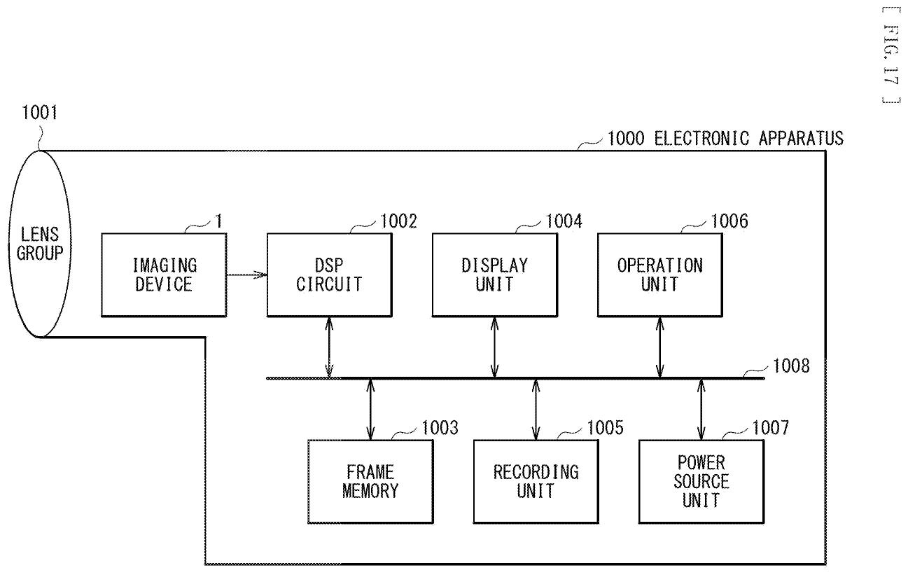

FIG. 16 schematically illustrates another example of a planar configuration of a Fresnel zone plate 38 as a modification example of the foregoing embodiment. Although in the foregoing embodiment, etc., the example is illustrated in which the light shielding zones 18A and the light transmitting zones 18B are disposed alternately in a substantially concentric circle pattern, the present disclosure is not limited to this. As illustrated in FIG. 16, for example, light-shielding zones 38A and light transmitting zones 38B may be disposed alternately in a substantially concentric rectangle pattern.

Also in such a configuration, similarly to the foregoing embodiment, in the left and right unit pixels P in which the Fresnel zone plate 38 is disposed, the strength distribution for the incident angle as illustrated in FIG, 5 is obtained. That is, it becomes possible to provide the infrared sensor including the image plane phase difference pixel P_{B}, which is able to acquire the parallax information, and having the focus detection function.

### 3. APPLICATION EXAMPLE

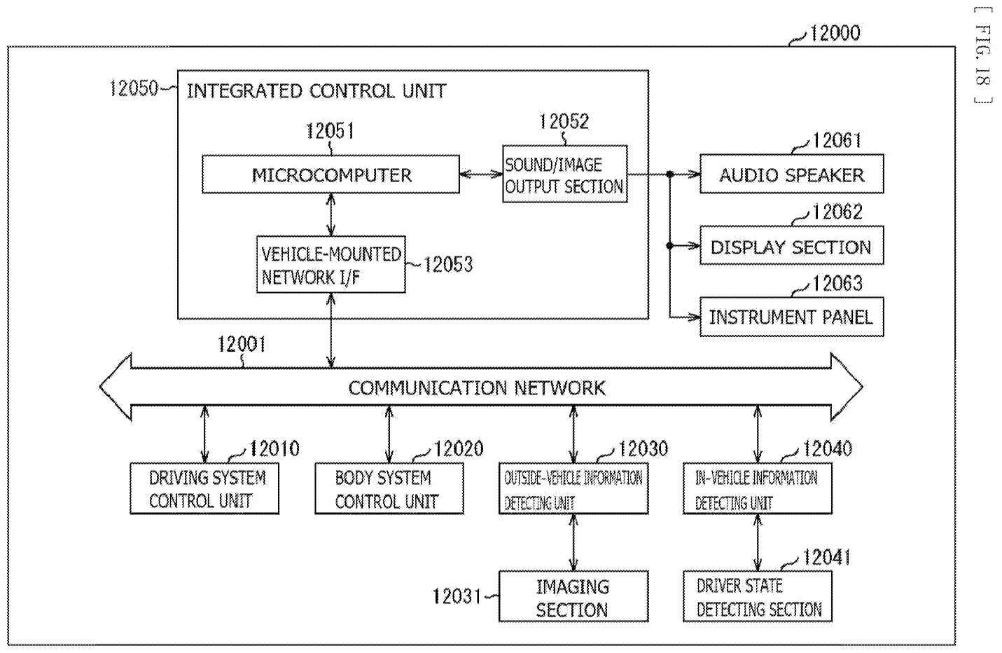

It is possible to apply the foregoing imaging device 1, or the like to all types of electronic apparatuses with an imaging function, for example, a camera system such as the digital still camera or the video camera, or a mobile phone with the imaging function. FIG. 17 illustrates an outline configuration of an electronic apparatus 1000.

The electronic apparatus 1000 includes, for example, a lens group 1001, the imaging device 1, a DSP (Digital Signal Processor) circuit 1002, a frame memory 1003, a display unit 1004, a recording unit 1005, an operation unit 1006, and a power source unit 1007, which are coupled to each other via a bus line 1008.

The lens group 1001 captures the entering light (image light) from the subject and forms an image on the imaging surface of the imaging device 1. The imaging device 1 converts the light amount of the entering light imaged by the lens group 1001 on the imaging surface, into the electric signal for each pixel, and supplies the electric signal to the DSP circuit 1002 as the pixel signal.

The DSP circuit 1002 is a signal processing circuit that processes the signal supplied from the imaging device 1. The DSP circuit 1002 outputs image data that is obtained by processing the signal from the imaging device 1. The frame memory 1003 temporarily holds the image data processed by the DSP circuit 1002 for each frame.

The display unit 1004 includes, for example, a panel-type display device such as a liquid crystal panel or an organic EL (Electro Luminescence) panel. The display unit 1004 records image data of moving images or still images imaged by the imaging device 1 in a recording medium such as a semiconductor memory or a hard disk.

The operation unit 1006 outputs operation signals for various types of functions of the electronic apparatus 1000 in accordance with user operations. The power source unit 1007 appropriately supplies various types of power sources, which are operation power sources for the DSP circuit 1002, the frame memory 1003, the display unit 1004, the recording unit 1005, and the operation unit 1006, to these supply targets.

### 4. PRACTICAL APPLICATION EXAMPLE

### Example of Application to Mobile Body

It is possible to apply a technology (present technology) according to the present disclosure to various products. For example, the technology according to the present disclosure may be implemented as a device to be mounted in any type of mobile bodies such as an automobile, an electric vehicle, a hybrid electric vehicle, a motorcycle, a bicycle, a personal mobility, an airplane, a drone, a vessel, and a robot.

FIG. 18 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 18, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a. vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 57, an audio speaker 12061, a display section 12062, and an instrument panel 12063 are illustrated as the output device. The display section 12062 may, for example, include at least one of an on-board display and a head-up display.

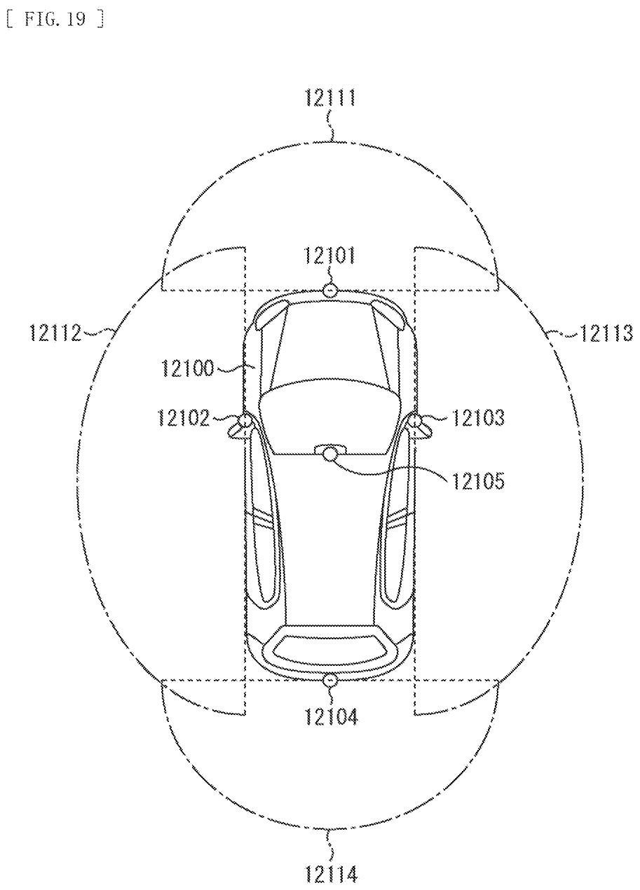

FIG. 19 is a diagram depicting an example of the installation position of the imaging section 12031.

In FIG. 19, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like,

Incidentally, FIG. 19 depicts an example of photographing ranges of the imaging sections 12101 to 12104, An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

As described above, description has been given of the example of the mobile body control system to which the technology according to the present disclosure may be applied. The technology according to the present disclosure may be applied to the imaging section 12031 among the configurations described above. Specifically, it is possible to apply an imaging device 100 to the imaging section 12031. The application of the technology according to the present disclosure to the imaging section 12031 makes it possible to perform highly precise control using shot images in the mobile body control system.

As described above, description has been given with reference to the embodiment, Modification Examples 1 to 7, Application Example, and Practical Application Example. However, content of the present disclosure is not limited to the foregoing embodiment, etc., and a variety of modifications is possible. For example, a layer configuration of each of the imaging devices aging device 1, for example) described in the foregoing embodiment, etc. is one example, and may further include another layer. In addition, a material or a thickness of each layer is one example and not limited to the above.

Moreover, in the foregoing embodiment, etc., although the example is illustrated in which the compound semiconductor is used as the constituent material of the photoelectric conversion layer 12, etc., the present disclosure is not limited to this. Even in a case where the present technology is applied to an imaging device configured by using an organic semiconductor, for example, it is possible to obtain effects similar to the effects listed in the foregoing embodiment, etc.

It is to be noted that the effects described herein are merely illustrative and not limited to descriptions of the effects, and may further include other effects.

It is to be noted that the present disclosure may take a configuration as described below. According to the technology of the following configuration, in the pixel array part in which the plurality of pixels is disposed in the row direction and the column direction, the optical member is disposed on the light entering side of the photoelectric conversion layer including the compound semiconductor to straddle the plurality of pixels adjacent at least in the row direction or the column direction. In the optical member, the first refractive index portion and the second refractive index portion having mutually different refractive indices are disposed alternately from the central part to the outer peripheral part. Consequently, the wavelengths passing through the optical member are focused at the photoelectric conversion layer. Therefore, it becomes possible to provide the imaging device and the electronic apparatus having the focus detection function.

(1)

An imaging device including:
a pixel array part in which a plurality of pixels is disposed in a row direction and a column direction;
a photoelectric conversion layer including a compound semiconductor; and
an optical member in which a first refractive index portion and a second refractive index portion having mutually different refractive indices are disposed alternately from a. central part to an outer peripheral part, the optical member being disposed on light entering side of the photoelectric conversion layer to straddle the plurality of pixels adjacent at least in the row direction or the column direction.
   (2)

The imaging device according to (1), in which the optical member is disposed to straddle the two pixels adjacent in the row direction or the column direction.

(3)

The imaging device according to (1), in which the optical member is disposed to straddle the four pixels adjacent in the row direction and the column direction.

(4)

The imaging device according to any one of (1) to (3), in which the first refractive index portion and the second refractive index portion are disposed alternately in a substantially concentric circle pattern or in a substantially concentric rectangle pattern.

(5)

The imaging device according to any one of (1) to (4), in which in the optical member, an optical path difference from each boundary between the first refractive index portion and the second refractive index portion, which are disposed alternately, to a focal point is an integral multiple of a half wavelength of a wavelength entering the photoelectric conversion layer.

(6)

The imaging device according to any one of (1) to (5), in which the first refractive index portion includes a light shielding member and the second refractive index portion includes a light transmitting member.

(7)

The imaging device according to any one of (1) to (6), in which the optical member includes a Fresnel zone plate.

(8)

The imaging device according to any one of (1) to (7), further including
a semiconductor substrate, an electrode layer, and a protective layer in this order, on the light entering side of the photoelectric conversion layer, in which
the optical member is embedded and formed on a surface opposed to the semiconductor substrate of the protective layer or inside the protective layer.
   (9)

The imaging device according to (8), in which a distance between the photoelectric conversion layer and the optical member is adjusted by a thickness of the protective layer,

(10)

The imaging device according to (8), in which a distance between the photoelectric conversion layer and the optical member is adjusted by a thickness of the semiconductor substrate.

(11)

The imaging device according to any one of (1) to (10), further including
an electrode layer on the light entering side of the photoelectric conversion layer, in which
the optical member includes the electrode layer and an air gap formed in the electrode layer.
   (12)

The imaging device according to any one of (1) to (11), in which the pixel array part includes a light shielding part between the pixels adjacent in the row direction and the column direction.

(13)

The imaging device according to (12), in which the light shielding part is embedded and formed in the photoelectric conversion layer,

(14)

The imaging device according to any one of (1) to (13), in which the optical member is disposed in all of the plurality of pixels that configure the pixel array part.

(15)

The imaging device according to any one of (1) to (14), in which the plurality of pixels in which the optical member is disposed is disposed at substantially equal intervals in the pixel array part.

(16)

The imaging device according to any one of (1) to (15), in which the photoelectric conversion layer absorbs at least wavelengths in a short-wavelength infrared region and generates electric charges.

(17)

The imaging device according to any one of (1) to (16), in which the compound semiconductor includes a group III-V semiconductor.

(18)

The imaging device according to any one of (1) to (17), in which the photoelectric conversion layer includes InₓGa₍₁₋ₓ₎As (0<x≤1).

(19)

An electronic apparatus including
an imaging device including
   a pixel array part in which a plurality of pixels is disposed in a row direction and a column direction,
   a photoelectric conversion layer including a compound semiconductor, and
   an optical member in which a first refractive index portion and a second refractive index portion having mutually different refractive indices are disposed alternately from a central part to an outer peripheral part, the optical member being disposed on light entering side of the photoelectric conversion layer to straddle the plurality of pixels adjacent at least in the row direction or the column direction.

It should be understood by those skilled in the art that various modifications, combinations, sub-combinations, and alterations may occur depending on design requirements and other factors insofar as they are within the scope of the appended claims or the equivalents thereof.

1. An imaging device comprising:
a pixel array part in which a plurality of pixels is disposed in a row direction and a column direction;
a photoelectric conversion layer including a compound semiconductor; and
an optical member in which a first refractive index portion and a second refractive index portion having mutually different refractive indices are disposed alternately from a central part to an outer peripheral part, the: optical member being disposed on light entering side of the photoelectric conversion layer to straddle the plurality of pixels adjacent at least in the row direction or the column direction.

2. The imaging device according to claim 1, wherein the optical member is disposed to straddle the two pixels adjacent in the row direction or the column direction.

3. The imaging device according to claim 1, wherein the optical member is disposed to straddle the four pixels adjacent in the row direction and the column direction.

4. The imaging device according to claim 1, wherein the first refractive index portion and the second refractive index portion are disposed alternately in a substantially concentric circle pattern or in a substantially concentric rectangle pattern.

5. The imaging device according to claim 1, wherein in the optical member, an optical path difference from each boundary between the first refractive index portion and the second refractive index portion, which are disposed alternately, to a focal point is an integral multiple of a half wavelength of a wavelength entering the photoelectric conversion layer.

6. The imaging device according to claim 1, wherein the first refractive index portion includes a light shielding member and the second refractive index portion includes a light transmitting member.

7. The imaging device according to claim 1, wherein the optical member comprises a Fresnel zone plate.

8. The imaging device according to claim 1, further comprising
a semiconductor substrate, an electrode layer, and a protective layer in this order, on the light entering side of the photoelectric conversion layer, wherein
the optical member is embedded and formed on a surface opposed to the semiconductor substrate of the protective layer or inside the protective layer.

9. The imaging device according to claim 8, wherein a distance between the photoelectric conversion layer and the optical member is adjusted by a thickness of the protective layer.

10. The imaging device according to claim 8, wherein a distance between the photoelectric conversion layer and the optical member is adjusted by a thickness of the semiconductor substrate.

11. The imaging device according to claim 1, further comprising
an electrode layer on the light entering side of the photoelectric conversion layer, wherein
the optical member includes the electrode layer and an air gap formed in the electrode layer.

12. The imaging device according to claim 1, wherein the pixel array part includes a light shielding part between the pixels adjacent in the row direction and the column direction.

13. The imaging device according to claim 12, wherein the light shielding part is embedded and formed in the photoelectric conversion layer.

14. The imaging device according to claim 1, wherein the optical member is disposed in all of the plurality of pixels that configure the pixel array part.

15. The imaging device according to claim 1. wherein the plurality of pixels in which the optical member is disposed is disposed at substantially equal intervals in the pixel array part.

16. The imaging device according to claim 1, wherein the photoelectric conversion layer absorbs at least wavelengths in a short-wavelength infrared region and generates electric charges.

17. The imaging device according to claim 1, wherein the compound semiconductor comprises a group semiconductor.

18. The imaging device according to claim 1, wherein the photoelectric conversion layer includes InₓGa₍₁₋ₓ₎As (0<x≤1).

19. An electronic apparatus comprising
an imaging device including
a pixel array part in which a plurality of pixels is disposed in a row direction and a column direction,
a photoelectric conversion layer including a compound semiconductor, and
an optical member in which a first refractive index portion and a second refractive index portion having mutually different refractive indices are disposed alternately from a central part to an outer peripheral part, the optical member being disposed on light entering side of the photoelectric conversion layer to straddle the plurality of pixels adjacent at least in the row direction or the column direction.
